(19) United States
(12) Patent Application Publication
(10) Pub. No.: US 2013/0065384 A1
(43) Pub. Date: Mar. 14, 2013

(54) METHOD FOR MANUFACTURING SILICON CARBIDE SEMICONDUCTOR DEVICE

(71) Applicants: Toru Hiyoshi, Osaka-shi (JP); Takeyoshi Masuda, Osaka-shi (JP); Keiji Wada, Osaka-shi (JP)

(72) Inventors: Toru Hiyoshi, Osaka-shi (JP); Takeyoshi Masuda, Osaka-shi (JP); Keiji Wada, Osaka-shi (JP)

(73) Assignee: Sumitomo Electric Industries, Ltd., Osaka-shi (JP)

(21) Appl. No.: 13/613,785

(22) Filed: Sep. 13, 2012

Related U.S. Application Data
(60) Provisional application No. 61/534,724, filed on Sep. 14, 2011.

(30) Foreign Application Priority Data
Sep. 14, 2011 (JP) 2011-200305

(51) Int. Cl. H01L 21/336

(52) U.S. Cl. 438/589; 257/E21.409

(57) ABSTRACT

A mask layer is formed on a silicon carbide layer by a deposition method. The mask layer is patterned. A gate trench having a side wall is formed by removing a portion of the silicon carbide layer by etching using the patterned mask layer as a mask. A gate insulating film is formed on the side wall of the gate trench. A gate electrode is formed on the gate insulating film. The silicon carbide layer has one of hexagonal and cubic crystal types, and the side wall of the gate trench substantially includes one of a{0-33-8} plane and a {01-1-4} plane in a case where the silicon carbide layer is of hexagonal crystal type, and substantially includes a {100} plane in a case where the silicon carbide layer is of cubic crystal type.

### BACKGROUND OF THE INVENTION

1. Field of the Invention

The present invention relates to a method for manufacturing a silicon carbide semiconductor device, and more particularly to a method for manufacturing a silicon carbide semiconductor device having a silicon carbide layer.

2. Description of the Background Art

Conventionally, it has been proposed to use silicon carbide (SiC) as a material for a semiconductor device. For example, it has been proposed to form a trench gate-type MOSFET (Metal Oxide Semiconductor Field Effect Transistor) using silicon carbide (see Japanese Patent Laying-Open No. 2008-235546 (Patent Literature 1)).

This publication proposes forming a gate trench having a gate electrode and a gate insulating film arranged therein to have a tapered side wall in order to improve breakdown voltage of the gate insulating film in a trench gate-type MOSFET. Specifically, by removing a portion of a semiconductor layer made of silicon carbide by anisotropic etching using an etching mask having an opening pattern, and thereafter performing isotropic etching, a gate trench is formed in the semiconductor layer to have a tapered side wall.

Here, for example, concerning silicon carbide of hexagonal crystal type, it has been conventionally reported that high channel mobility can be achieved by utilizing a so-called semi-polar plane such as a plane having a plane orientation of {0-33-8} as a channel in a semiconductor device such as a MOSFET. However, Patent Literature 1 does not disclose forming a semi-polar plane as described above as a channel in a trench gate-type MOSFET (i.e., forming a gate trench to have a side wall constituted by a semi-polar plane). Merely processing a side wall of a gate trench by isotropic etching to have a tapered shape as disclosed in this publication does not result in a formed side wall which accurately corresponds to the above-described semi-polar plane. In this case, there has been a problem that characteristics (for example, channel mobility) of a formed semiconductor device are not sufficiently improved.

In addition, the above publication does not disclose a concrete method for forming the etching mask for forming the gate trench. The inventors of the present invention have found that, if the forming method is inappropriate, a recess is formed in an inner side of the gate trench, which may cause a reduction in breakdown voltage.

### SUMMARY OF THE INVENTION

The present invention has been made to solve the foregoing problems, and one object of the present invention is to provide a method for manufacturing a silicon carbide semiconductor device capable of obtaining a high-quality semiconductor device having stable characteristics.

A method for manufacturing a silicon carbide semiconductor device in accordance with the present invention includes the steps of: preparing a silicon carbide layer having a main surface; forming a mask layer on the main surface by a deposition method; patterning the mask layer; forming a gate trench having a side wall by removing a portion of the silicon carbide layer by etching using the patterned mask layer as a mask; forming a gate insulating film on the side wall of the gate trench; and forming a gate electrode on the gate insulating film. The silicon carbide layer has one of hexagonal and cubic crystal types, and the side wall of the gate trench substantially includes one of a {0-33-8} plane and a {01-1-4} plane in a case where the silicon carbide layer is of hexagonal crystal type, and substantially includes a {100} plane in a case where the silicon carbide layer is of cubic crystal type.

Here, the expression “the side wall substantially includes one of the {0-33-8} plane and the { 01-1-4} plane” refers to a case where a crystal plane constituting the side wall is one of the {0-33-8} plane and the {01-1-4} plane, and a case where the crystal plane constituting the side wall is a plane having an off angle of not less than −3° and not more than 3° relative to the {0-33-8} plane or the {01-1-4} plane in the <1-100> direction. It should be noted that the “off angle relative to the {0-33-8} plane or the {01-1-4} plane in the <1-100> direction” refers to an angle formed by an orthogonal projection of a normal line of the above-described side wall to a flat plane defined by the <1-100> direction and the <0001> direction, and a normal line of the {0-33-8} plane or the {01-1-4} plane. The sign of positive value corresponds to a case where the orthogonal projection approaches in parallel with the <1-100> direction whereas the sign of negative value corresponds to a case where the orthogonal projection approaches in parallel with the <0001> direction. Further, the expression “the side wall substantially includes the {100} plane” refers to a case where the crystal plane constituting the side wall is the {100} plane, and a case where the crystal plane constituting the side wall is a crystal plane having an off angle of not less than −3° and not more than 3° relative to the {100} plane in any crystal orientation.

According to the manufacturing method, the side wall of the gate trench substantially corresponds to any one of the {0-33-8} plane, the {01-1-4} plane, and the {100} plane, that is, a stable semi-polar plane. By utilizing such a side wall as a channel, a high-quality semiconductor device can be manufactured.

Further, according to the manufacturing method, since the mask layer is formed by the deposition method, formation of a recess in an inner side of the gate trench can be prevented, when compared with a case where the mask layer is formed by a thermal oxidation method. Thereby, a reduction in breakdown voltage due to electric field concentration which occurs in this recess can be avoided.

Preferably, the step of forming the mask layer is performed by depositing one or more materials selected from silicon oxide, silicon nitride, aluminum oxide, aluminum nitride, and gallium nitride. Since these materials are excellent in hot corrosion resistance, the mask layer made of these materials is suitable as a mask layer for etching that uses a corrosive atmosphere under a high temperature.

Preferably, the step of forming the gate trench includes the step of performing thermal etching. Thereby, the side wall having the above plane orientation can be spontaneously formed. Further, formation of a process-damaged layer in the side wall can be prevented.

Preferably, the step of performing the thermal etching is performed by heating the silicon carbide layer while exposing the silicon carbide layer to a reactive gas containing oxygen and chlorine. The inventors have found that, by heating a silicon carbide layer (silicon carbide single-crystal layer) while exposing the silicon carbide layer to a reactive gas containing oxygen and chlorine, a crystal plane allowing for the slowest etching rate is spontaneously formed in the silicon carbide. The inventors have also found that, by adjusting composition of the reactive gas (for example, the ratio between oxygen and chlorine) and heating temperature, the {0-33-8} plane, the {01-1-4} plane, or the {100} plane described above can be spontaneously formed.

Preferably, the step of forming the gate trench includes the step of performing etching having a sputtering effect before performing the thermal etching. More preferably, the etching having the sputtering effect is reactive ion etching. Thereby, even if a residue is left within an opening pattern in the mask layer, the residue is also removed together with a portion of the silicon carbide layer by the etching having the sputtering effect. Accordingly, the residue is already removed when the thermal etching is performed thereafter. This can suppress variations in the thermal etching due to the residue.

According to the present invention, a high-quality silicon carbide semiconductor device having stable characteristics can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view showing a first embodiment of a semiconductor device in accordance with the present invention.

FIG. 2 is a schematic cross sectional view for illustrating a method for manufacturing the semiconductor device shown in FIG. 1.

FIG. 3 is a schematic cross sectional view for illustrating the method for manufacturing the semiconductor device shown in FIG. 1.

FIG. 4 is a schematic cross sectional view for illustrating the method for manufacturing the semiconductor device shown in FIG. 1.

FIG. 5 is a schematic cross sectional view for illustrating the method for manufacturing the semiconductor device shown in FIG. 1.

FIG. 6 is a schematic cross sectional view for illustrating the method for manufacturing the semiconductor device shown in FIG. 1.

FIG. 7 is a schematic cross sectional view for illustrating the method for manufacturing the semiconductor device shown in FIG. 1.

FIG. 8 is a schematic cross sectional view for illustrating the method for manufacturing the semiconductor device shown in FIG. 1.

FIG. 9 is a schematic cross sectional view for illustrating the method for manufacturing the semiconductor device shown in FIG. 1.

FIG. 10 is a schematic cross sectional view for illustrating the method for manufacturing the semiconductor device shown in FIG. 1.

FIG. 11 is a schematic cross sectional view for illustrating the method for manufacturing the semiconductor device shown in FIG. 1.

FIG. 12 is a schematic cross sectional view for illustrating a method for manufacturing a semiconductor device in a comparative example.

FIG. 13 is an enlarged view of a region XIII in FIG. 12.

FIG. 14 is a schematic cross sectional view for illustrating the method for manufacturing the semiconductor device in the comparative example.

FIG. 15 is a schematic cross sectional view for illustrating the semiconductor device in the comparative example.

FIG. 16 is a schematic cross sectional view for illustrating a variation of the method for manufacturing the semiconductor device shown in FIG. 1.

FIG. 17 is a schematic cross sectional view for illustrating the variation of the method for manufacturing the semiconductor device shown in FIG. 1.

FIG. 18 is a schematic cross sectional view showing a variation of the semiconductor device shown in FIG. 1.

FIG. 19 is a schematic cross sectional view showing a second embodiment of the semiconductor device in accordance with the present invention.

FIG. 20 is a schematic cross sectional view for illustrating a method for manufacturing the semiconductor device shown in FIG. 19.

FIG. 21 is a schematic cross sectional view for illustrating the method for manufacturing the semiconductor device shown in FIG. 19.

FIG. 22 is a schematic cross sectional view for illustrating the method for manufacturing the semiconductor device shown in FIG. 19.

FIG. 23 is a schematic cross sectional view for illustrating the method for manufacturing the semiconductor device shown in FIG. 19.

FIG. 24 is a schematic cross sectional view for illustrating the method for manufacturing the semiconductor device shown in FIG. 19.

FIG. 25 is a schematic cross sectional view for illustrating the method for manufacturing the semiconductor device shown in FIG. 19.

FIG. 26 is a schematic cross sectional view for illustrating the method for manufacturing the semiconductor device shown in FIG. 19.

FIG. 27 is a schematic cross sectional view for illustrating the method for manufacturing the semiconductor device shown in FIG. 19.

FIG. 28 is a schematic cross sectional view showing a variation of the semiconductor device shown in FIG. 19.

FIG. 29 is an enlarged partial schematic cross sectional view of a side wall of a silicon carbide layer.

FIG. 30 is a scanning electron microscope photograph showing a result of an experiment on a sample 1.

FIG. 31 is a scanning electron microscope photograph showing a result of an experiment on a sample 2.

### DESCRIPTION OF THE PREFERRED EMBODIMENTS

The following describes embodiments of the present invention with reference to the drawings. It should be noted that in the below-mentioned drawings, the same or corresponding portions are given the same reference characters and are not described repeatedly. Further, in the crystallographic description in the present specification, an individual orientation is represented by [ ], a group orientation is represented by < >, an individual plane is represented by ( ) and a group plane is represented by { }. In addition, a negative index is supposed to be crystallographically indicated by putting “-” (bar) above a numeral, but is indicated by putting the negative sign before the numeral in the present specification.

### First Embodiment

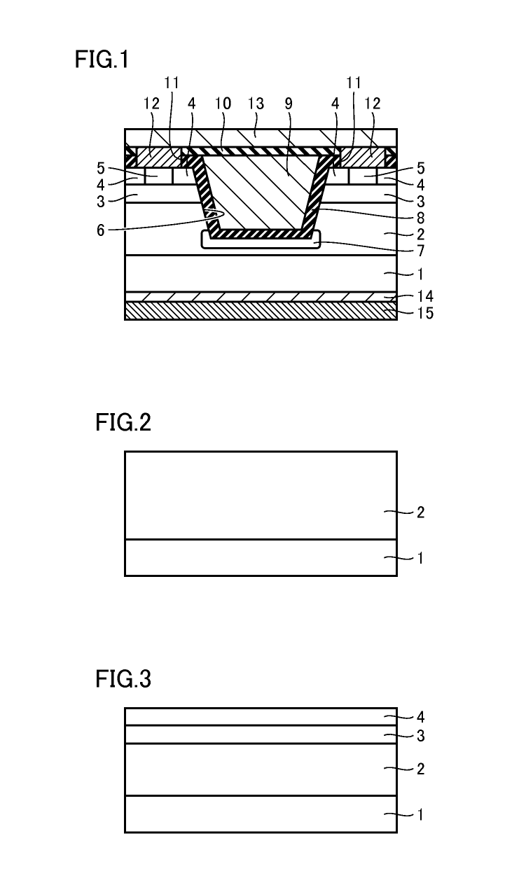

Referring to FIG. 1, a semiconductor device in accordance with the present invention is a vertical type MOSFET, which is a vertical type device employing a gate trench having an inclined side wall. The semiconductor device has a substrate 1 having n type conductivity, and a silicon carbide layer epitaxially formed on a main surface (an upper surface in the drawing) of substrate 1. Substrate 1 is made of silicon carbide of hexagonal crystal type or silicon carbide of cubic crystal type. Accordingly, the silicon carbide layer epitaxially formed on substrate 1 is also made of silicon carbide of hexagonal crystal type or silicon carbide of cubic crystal type. The silicon carbide layer has a breakdown voltage holding layer 2 serving as an epitaxial layer having n type conductivity, p type body layers 3 having p type conductivity, n type source contact layers 4 having n type conductivity, and contact regions 5 having p type conductivity. Further, the semiconductor device has a gate insulating film 8, a gate electrode 9, an interlayer insulating film 10, source electrodes 12, a source wire electrode 13, a drain electrode 14, and a backside surface protecting electrode 15.

Breakdown voltage holding layer 2 is foamed on one main surface of substrate 1. Each of p type body layers 3 is formed on breakdown voltage holding layer 2. On p type body layer 3, n type source contact layer 4 is formed. P type contact region 5 is formed to be surrounded by n type source contact layers 4. A gate trench 6 is formed by removing portions of n type source contact layer 4, p type body layer 3, and breakdown voltage holding layer 2. Each of the side walls of gate trench 6 is inclined relative to the main surface (upper surface in the drawing) of substrate 1. In other words, each of the side walls of gate trench 6 is inclined relative to a main surface (upper surface in the drawing) of the silicon carbide layer. The inclined side wall surrounds a projection portion (upper portions of n type source contact layer 4 and contact region 5) in the silicon carbide layer. If substrate 1 is of hexagonal crystal type, the projection portion may have, for example, a hexagonal planar shape. Further, if substrate 1 is of cubic crystal type, the projection portion may have, for example, a quadrangular planar shape.

Gate insulating film 8 is formed on the side walls and bottom wall of gate trench 6. Gate insulating film 8 extends onto the upper surface of each of n type source contact layers 4. Gate electrode 9 is formed on gate insulating film 8 to fill the inside of gate trench 6. Gate electrode 9 has an upper surface substantially as high as the upper surface of a portion of gate insulating film 8 on the upper surface of each of n type source contact layers 4.

Interlayer insulating film 10 is formed to cover gate electrode 9 as well as the portion of gate insulating film 8 extending onto the upper surface of each of n type source contact layers 4. By removing portions of interlayer insulating film 10 and gate insulating film 8, openings 11 are formed to expose portions of n type source contact layers 4 and p type contact regions 5. Source electrodes 12 are formed in contact with p type contact regions 5 and the portions of n type source contact layers 4 so as to fill the inside of openings 11. Source wire electrode 13 is formed in contact with the upper surface of each of source electrodes 12 so as to extend on the upper surface of interlayer insulating film 10. Further, drain electrode 14 is formed on the backside surface of substrate 1 opposite to its main surface on which breakdown voltage holding layer 2 is formed. This drain electrode 14 is an ohmic electrode. Drain electrode 14 has a surface which is opposite to its surface facing substrate 1 and on which backside surface protecting electrode 15 is formed.

In the semiconductor device shown in FIG. 1, each of the side walls of gate trench 6 is inclined and substantially corresponds to one of a {0-33-8} plane and a {01-1-4} plane in a case where the silicon carbide layer constituting p type body layer 3 and the like is of hexagonal crystal type. Further, the inclined side wall of gate trench 6 substantially corresponds to a {100} plane in a case where the silicon carbide layer constituting p type body layer 3 and the like is of cubic crystal type. As seen from FIG. 1, each of the side walls thus corresponding to the so-called semi-polar plane can be used as a channel region, which is an active region of the semiconductor device. Because each of the side walls corresponds to the stable crystal plane, leakage current can be reduced sufficiently and high breakdown voltage can be obtained in a case where such a side wall is employed for the channel region, as compared with a case where another crystal plane (such as a (0001) plane) is employed for the channel region.

The following briefly describes operations of the semiconductor device shown in FIG. 1. Referring to FIG. 1, when a voltage equal to or smaller than a threshold value is applied to gate electrode 9, i.e., when the semiconductor device is in an OFF state, p type body layer 3 and breakdown voltage holding layer 2 of n type conductivity are reverse-biased. Hence, they are in a non-conductive state. On the other hand, when gate electrode 9 is fed with a positive voltage, an inversion layer is formed in the channel region near a region of p type body layer 3 in contact with gate insulating film 8. Accordingly, n type source contact layer 4 and breakdown voltage holding layer 2 are electrically connected to each other. As a result, a current flows between source electrode 12 and drain electrode 14.

The following describes a method for manufacturing the semiconductor device shown in FIG. 1 in accordance with the present invention, with reference to FIG. 2 to FIG. 11.

First, referring to FIG. 2, on the main surface of substrate 1 made of silicon carbide, an epitaxial layer of silicon carbide with n type conductivity is formed. The epitaxial layer includes a portion serving as breakdown voltage holding layer 2. Breakdown voltage holding layer 2 is formed by means of epitaxial growth employing a CVD method that utilizes a mixed gas of silane (SiH₄) and propane (C₃H₈) as a material gas and utilizes hydrogen gas (H₂) as a carrier gas, for example. In doing so, it is preferable to introduce nitrogen (N) or phosphorus (P) as an impurity of n type conductivity, for example. Breakdown voltage holding layer 2 can contain the n type impurity at a concentration of, for example, not less than 5×10¹⁵ cm⁻³ and not more than 5×10¹⁶ cm³.

Next, ions are implanted into the upper surface layer of breakdown voltage holding layer 2, thereby forming p type body layer 3 and n type source contact layer 4. In the ion implantation for forming p type body layer 3, ions of an impurity of p type conductivity such as aluminum (Al) are implanted. In doing so, by adjusting acceleration energy of the ions to be implanted, the depth of the region in which p type body layer 3 is to be formed can be adjusted.

Next, ions of an impurity of n type conductivity are implanted into breakdown voltage holding layer 2 thus having p type body layer 3 formed therein, thereby forming n type source contact layer 4. An exemplary, usable n type impurity is phosphorus or the like. In this way, a structure shown in FIG. 3 is obtained.

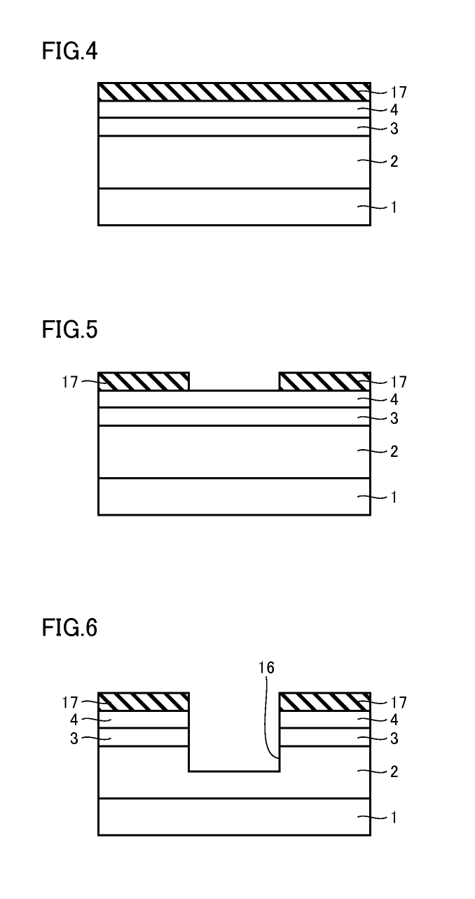

Next, as shown in FIG. 4, a mask layer 17 is formed on n type source contact layer 4, that is, on the main surface (upper surface in the drawing) of the silicon carbide layer, by a deposition method. The deposition method used herein is a method characterized in that all materials for a film to be formed are externally supplied. Thus, the deposition method does not include a thermal oxidation method, that is, a method utilizing an element already existing in a region where a film is to be formed, as a part of materials. As the deposition method, for example, a CVD (Chemical Vapor Deposition) method, a sputtering method, or a resistance heating evaporation method can be used. Preferably, the step of forming mask layer 17 is performed by depositing one or more materials selected from silicon oxide, silicon nitride, aluminum oxide, aluminum nitride, and gallium nitride.

Next, as shown in FIG. 5, mask layer 17 is patterned. Patterning of mask layer 17 can be performed, for example, by means of a photolithography method. It should be noted that an opening pattern in mask layer 17 has a width of, for example, not less than 0.1 μm and not more than 2 μm.

Next, by removing a portion of the silicon carbide layer by etching using patterned mask layer 17 as a mask, gate trench 6 (FIG. 1) having the side walls is formed. Specifically, the following steps are performed.

First, as shown in FIG. 6, using mask layer 17 as a mask, portions of n type source contact layer 4, p type body layer 3, and breakdown voltage holding layer 2 are removed by means of etching having a sputtering effect (physical etching effect). As such an etching method, for example, ion milling, or reactive ion etching (RIB), in particular, inductively coupled plasma (ICP) RIE can be used. Specifically, for example, ICP-RIE can be used which employs SF₆ or a mixed gas of SF₆ and O₂ as a reactive gas. By means of such etching, prior to formation of gate trench 6, a vertical trench 16 having side walls substantially perpendicular to the main surface of substrate 1 is formed in a region where gate trench 6 shown in FIG. 1 is to be formed.

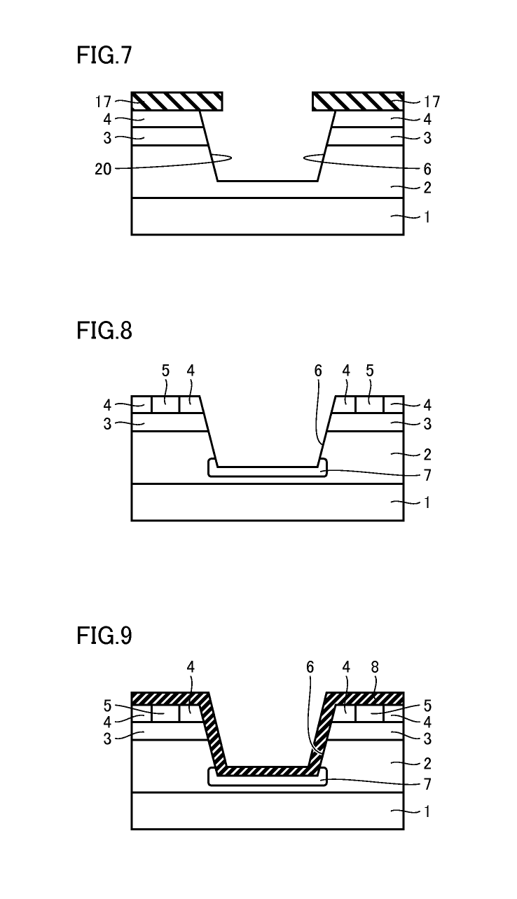

Next, as shown in FIG. 7, thermal etching is performed. Specifically, treatment of heating the silicon carbide layer while exposing the silicon carbide layer to a reactive gas is performed. Thereby, a predetermined crystal plane is exhibited in each of breakdown voltage holding layer 2, p type body layer 3, and n type source contact layer 4. In other words, by performing the thermal etching on the side walls of vertical trench 16 shown in FIG. 6, gate trench 6 having side walls 20 inclined relative to the main surface of substrate 1 as shown in FIG. 7 can be formed.

In order to form the predetermined crystal plane, a mixed gas of oxygen gas and chlorine gas is preferably used as the reactive gas. In supplying the mixed gas, a ratio of a flow rate of the oxygen gas to a flow rate of the chlorine gas is preferably set to not less than 0.1 and not more than 2.0, and more preferably set to not less than 0.25. It should be noted that the reactive gas may contain a carrier gas in addition to the chlorine gas and the oxygen gas. An exemplary, usable carrier gas is nitrogen (N₂) gas, argon gas, helium gas, or the like. Further, heat treatment temperature in the thermal etching is preferably set to not less than 700° C. and not more than 1200° C. By setting the heat treatment temperature to not less than 700° C., an etching rate of SiC of about 70 μm/hr can be ensured. The lower limit temperature is more preferably set to not less than 800° C., and further preferably set to not less than 900° C. The upper limit temperature is more preferably set to not more than 1100° C., and further preferably set to not more than 1000° C. In addition, if silicon oxide, silicon nitride, aluminum oxide, aluminum nitride, or gallium nitride is used as a material for mask layer 17 on this occasion, etching selectivity of SiC with respect to the material for mask layer 17 can be extremely increased, and thus consumption of mask layer 17 during etching of SiC can be suppressed.

It should be noted that the crystal plane exhibited at each of side walls 20 corresponds to, for example, the {0-33-8} plane. Namely, in the etching under the above-described conditions, side wall 20 of gate trench 6 is spontaneously formed to correspond to the {0-33-8} plane, which is a crystal plane allowing for the slowest etching rate. As a result, a structure as shown in FIG. 7 is obtained. It should be noted that the crystal plane constituting side wall 20 may be the {01-1-4} plane. Further, in the case where the silicon carbide layer constituting breakdown voltage holding layer 2 and the like is of cubic crystal type, the crystal plane constituting side wall 20 may be the {100} plane. Preferably, a (0-33-8) plane is used as the {0-33-8} plane, and a (01-1-4) plane is used as the {01-1-4} plane.

It should be noted that, if there is a process-damaged layer in the side walls of vertical trench 16, the process-damaged layer can be removed by sufficiently increasing a time period for the thermal etching step. In order to remove the damaged layer more reliably, it is preferable to perform the thermal etching on the side walls of vertical trench 16 over a depth of not less than 0.1 μm.

Next, mask layer 17 is removed by any method such as etching. Gate trench 6 is thus formed.

Thereafter, a resist film (not shown) having a predetermined pattern is formed using the photolithography method so as to extend from the inside of gate trench 6 onto each of the upper surfaces of n type source contact layers 4. As the resist film, there can be used a resist film having an opening pattern in conformity with the bottom portion of gate trench 6 and a portion of the upper surface of n type source contact layer 4. By implanting ions of an impurity of p type conductivity using this resist film as a mask, an electric field relaxing region 7 is formed at the bottom portion of gate trench 6, and contact region 5 of p type conductivity is formed at the region of the portion of n type source contact layer 4. Thereafter, the resist film is removed. As a result, a structure as shown in FIG. 8 is obtained.

Then, an activation annealing step is performed to activate the impurity implanted by means of the above-described ion implantation. In this activation annealing step, annealing treatment is performed without forming a particular cap layer on the surface of the epitaxial layer made of silicon carbide. Here, the inventors have found that even when activation annealing treatment is performed without forming a protective film such as the cap layer on the surface thereof in the case where the above-described {0-33-8} plane is employed, a property of the surface is never deteriorated and sufficient surface smoothness can be maintained. Thus, the conventionally required step of forming the protective film (cap layer) before the activation annealing treatment is omitted and the activation annealing step is directly performed. It should be noted that the above-described cap layer may be formed before performing the activation annealing step. Alternatively, for example, the cap layer may be provided only on the upper surfaces of n type source contact layer 4 and p type contact region 5 before performing the activation annealing treatment.

Next, as shown in FIG. 9, gate insulating film 8 is formed to extend from the inside of gate trench 6 onto the upper surfaces of n type source contact layer 4 and p type contact region 5. Accordingly, the gate insulating film is formed on the side walls of gate trench 6. As gate insulating film 8, for example, there can be used an oxide film (silicon oxide film) obtained by thermally oxidizing an epitaxial layer made of silicon carbide.

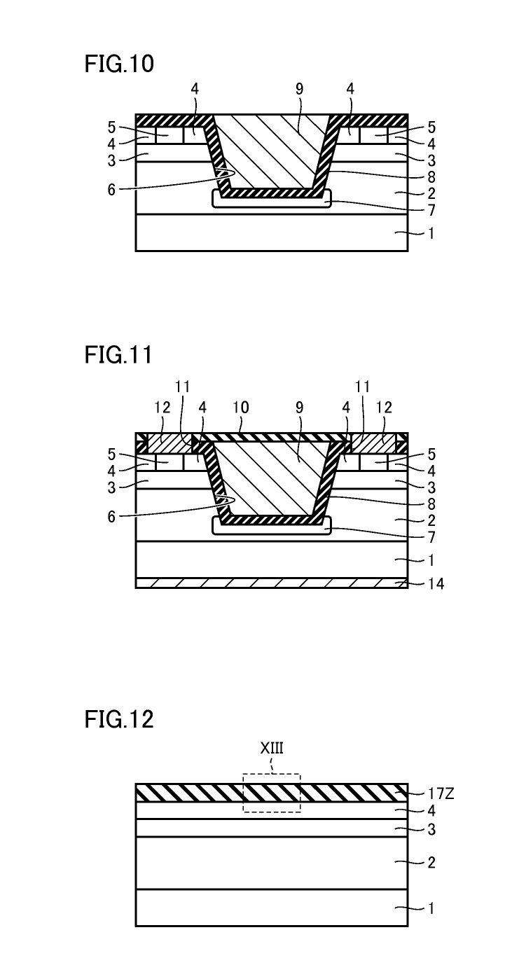

Next, as shown in FIG. 10, gate electrode 9 is formed on gate insulating film 8 so as to fill the inside of gate trench 6. As a method for forming gate electrode 9, the following method can be used, for example. First, a sputtering method or the like is employed to form a conductor film on gate insulating film 8. The conductor film is to be the gate electrode extending to the inside of gate trench 6 and to a region on p type contact region 5. The conductor film may be made of any material such as a metal as long as the material has conductivity. Thereafter, an appropriate method such as an etch back method or a CMP (Chemical Mechanical Polishing) method is used to remove a portion of the conductor film formed on regions other than the inside of gate trench 6. As a result, the conductor film filling the inside of gate trench 6 remains to constitute gate electrode 9.

Next, interlayer insulating film 10 (see FIG. 11) is formed to cover the upper surface of gate electrode 9 and the upper surface of gate insulating film 8 exposed on p type contact region 5. The interlayer insulating film can be made of any material as long as the material is insulative. Further, a resist film having a pattern is formed on interlayer insulating film 10, using the photolithography method. The resist film (not shown) is provided with an opening pattern formed in conformity with a region on p type contact region 5.

Using this resist film as a mask, portions of interlayer insulating film 10 and gate insulating film 8 are removed by means of etching. As a result, openings 11 (see FIG. 11) are formed to extend through interlayer insulating film 10 and gate insulating film 8. Each of openings 11 has a bottom portion at which p type contact region 5 and a portion of n type source contact layer 4 are exposed. Thereafter, a conductor film to serve as source electrode 12 (see FIG. 11) is formed to fill the inside of opening 11 and cover the upper surface of the above-described resist film. Thereafter, the resist film is removed using a chemical solution or the like, thereby simultaneously removing the portion of the conductor film formed on the resist film (lift-off). As a result, the conductor film filling the inside of opening 11 constitutes source electrode 12. This source electrode 12 is an ohmic electrode making ohmic contact with p type contact region 5 and n type source contact layer 4.

Further, drain electrode 14 (see FIG. 11) is formed on the backside surface of substrate 1 (the surface thereof opposite to the main surface thereof on which breakdown voltage holding layer 2 is formed). Drain electrode 14 can be made of any material as long as the material allows for ohmic contact with substrate 1. In this way, a structure shown in FIG. 11 is obtained.

Thereafter, an appropriate method such as the sputtering method is employed to form source wire electrode 13 (see FIG. 1) and backside surface protecting electrode 15 (see FIG. 1). Source wire electrode 13 makes contact with each of the upper surfaces of source electrodes 12, and extends on the upper surface of interlayer insulating film 10. Backside surface protecting electrode 15 is formed on the surface of drain electrode 14. As a result, the semiconductor device shown in FIG. 1 can be obtained.

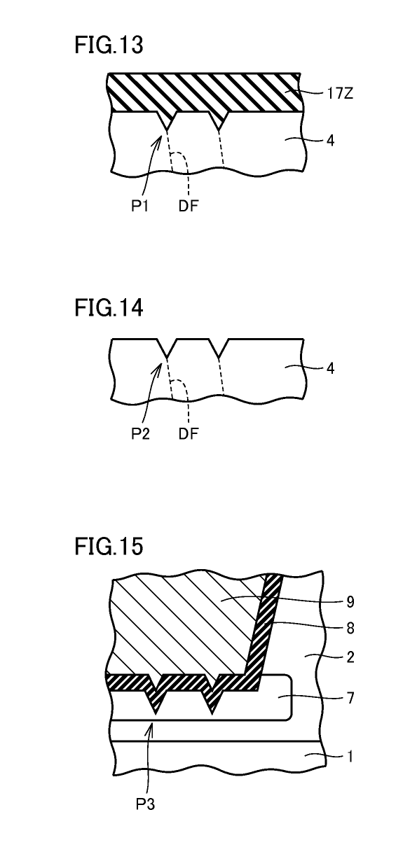

The following describes a manufacturing method in a comparative example. In the comparative example, a mask layer 17Z (FIG. 12) is formed by the thermal oxidation method instead of mask layer 17 (FIG. 4) formed by the deposition method. In a silicon carbide layer, a crystal defect DF such as threading dislocation may exist, and in this case, thermal oxidation proceeds faster at the location of crystal defect DF. As a result, a protrusion P1 (FIG. 13) eroding the silicon carbide layer is formed in mask layer 17Z. When an opening is formed in mask layer 17Z at the location of protrusion P1 and the periphery thereof by patterning mask layer 17Z, a recess P2 (FIG. 14) is formed in the silicon carbide layer to correspond to protrusion P1. Recess P2 remains even after etching, and as a result, a protrusion P3 is formed in gate electrode 9 covered with gate insulating film 8 in the semiconductor device. At the location of protrusion P3, electric field concentration is likely to occur while the semiconductor device is being used, which results in a reduction in breakdown voltage of the semiconductor device.

In contrast, according to the present embodiment, since mask layer 17 (FIG. 4) is formed by the deposition method, mask layer 17 does not erode the silicon carbide layer during formation of mask layer 17, unlike the above comparative example. Therefore, a reduction in breakdown voltage that may occur in the comparative example can be avoided.

The following describes a variation of the method for manufacturing the semiconductor device shown in FIG. 1 in accordance with the present invention.

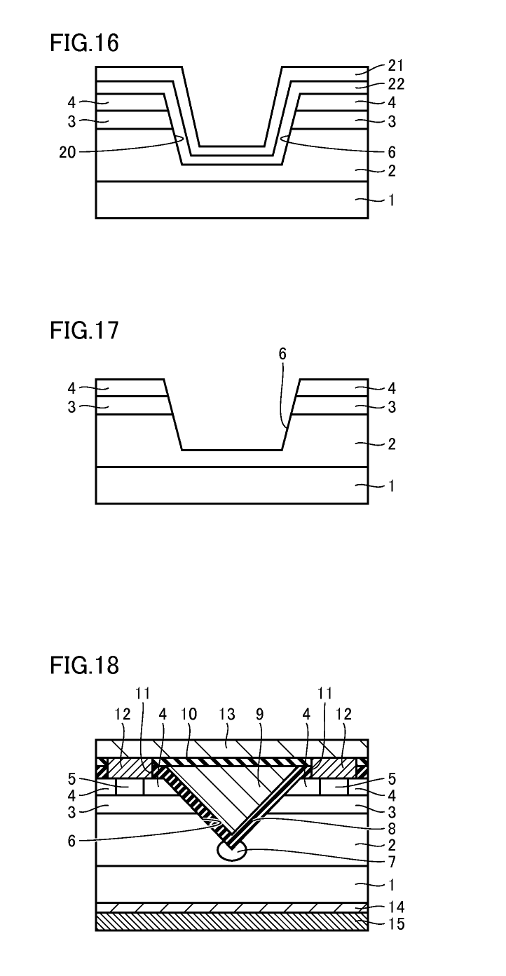

In the variation, the steps shown in FIG. 2 to FIG. 6 are performed first. Thereafter, mask layer 17 shown in FIG. 6 is removed. Next, a Si film 21 (see FIG. 16) made of silicon is formed to extend from the inside of vertical trench 16 to the upper surface of n type source contact layer 4. In this state, heat treatment is performed to cause reconstitution of silicon carbide at a region in contact with Si film 21 on the inner circumferential surface of vertical trench 16 and the upper surface of n type source contact layer 4. Accordingly, a reconstitution layer 22 of silicon carbide is formed as shown in FIG. 16 such that each of the side walls of the trench corresponds to a predetermined crystal plane ({0-33-8} plane). As a result, a structure as shown in FIG. 16 is obtained.

Thereafter, remaining Si film 21 is removed. Si film 21 can be removed by means of, for example, etching that uses a mixed liquid (gas) of HNO₃ and HF or the like. Thereafter, reconstitution layer 22 described above is further removed by means of etching. As the etching for removing reconstitution layer 22, ICP-RIE can be used. As a result, gate trench 6 having its inclined side walls as shown in FIG. 17 can be formed.

Thereafter, by performing the above-described steps shown in FIG. 8 to FIG. 11, the semiconductor device shown in FIG. 1 can be obtained.

Next, referring to FIG. 18, a variation of the semiconductor device shown in FIG. 1 is described. A semiconductor device shown in FIG. 18 basically has the same configuration as that of the semiconductor device shown in FIG. 1, but is different therefrom in terms of the shape of gate trench 6. Specifically, in the semiconductor device shown in FIG. 18, gate trench 6 has a V-shaped cross sectional shape. Further, from a different point of view, gate trench 6 of the semiconductor device shown in FIG. 18 has side walls inclined relative to the main surface of substrate 1, opposite to each other, and connected to each other at their lower portions. At the bottom portion of gate trench 6 (the portion at which the lower portions of the opposite side walls are connected to each other), electric field relaxing region 7 is formed. With the semiconductor device thus configured, there can be provided the same effect as that of the semiconductor device shown in FIG. 1. Further, in the semiconductor device shown in FIG. 18, gate trench 6 does not have a flat bottom surface as shown in FIG. 1. Accordingly, gate trench 6 shown in FIG. 18 has a width narrower than that of gate trench 6 shown in FIG. 1. As a result, the semiconductor device shown in FIG. 18 can be reduced in size as compared with the semiconductor device shown in FIG. 1. This is advantageous in attaining finer design and higher integration in the semiconductor device.

### Second Embodiment

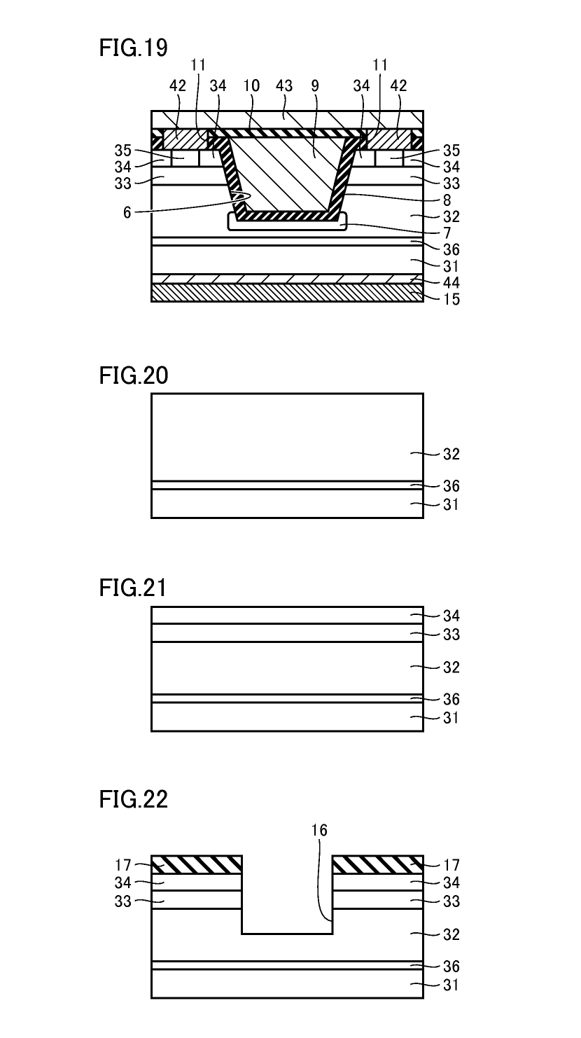

Referring to FIG. 19, the following describes a second embodiment of the semiconductor device in accordance with the present invention.

Referring to FIG. 19, the semiconductor device in accordance with the present invention is an IGBT, which is a vertical type device utilizing a gate trench having an inclined side wall. The semiconductor device shown in FIG. 19 has a substrate 31 having p type conductivity, and a silicon carbide layer epitaxially formed on a main surface (an upper surface in the drawing) of substrate 31. Substrate 31 is made of silicon carbide of hexagonal crystal type or silicon carbide of cubic crystal type. Accordingly, the silicon carbide layer epitaxially formed on substrate 31 is also made of silicon carbide of hexagonal crystal type or silicon carbide of cubic crystal type. The silicon carbide layer has a p type epitaxial layer 36 serving as a buffer layer having p type conductivity, an n type epitaxial layer 32 serving as a breakdown voltage holding layer having n type conductivity, p type semiconductor layers 33 corresponding to a well region having p type conductivity, n type emitter contact layers 34 having n type conductivity, and contact regions 35 having p type conductivity. Further, the semiconductor device has gate insulating film 8, gate electrode 9, interlayer insulating film 10, emitter electrodes 42, an emitter wire electrode 43, a collector electrode 44, and backside surface protecting electrode 15.

P type epitaxial layer 36 is formed on one main surface of substrate 31. On p type epitaxial layer 36, n type epitaxial layer 32 is formed. On n type epitaxial layer 32, each of p type semiconductor layers 33 is formed. On p type semiconductor layer 33, n type emitter contact layer 34 is formed. P type contact region 35 is formed to be surrounded by n type emitter contact layers 34. Gate trench 6 is formed by removing portions of n type emitter contact layer 34, p type semiconductor layer 33, and n type epitaxial layer 32. Each of the side walls of gate trench 6 is inclined relative to the main surface of substrate 31. In other words, each of the side walls of gate trench 6 is inclined relative to a main surface (upper surface in the drawing) of the silicon carbide layer. The inclined side wall surrounds a projection portion (projection-shaped portion having an upper surface on which emitter electrode 42 is formed). If substrate 31 is of hexagonal crystal type, the projection portion may have, for example, a hexagonal planar shape. Further, if substrate 31 is of cubic crystal type, the projection portion may have, for example, a quadrangular planar shape.

Gate insulating film 8 is formed on the side walls and bottom wall of gate trench 6. Gate insulating film 8 extends onto the upper surface of n type emitter contact layer 34. Gate electrode 9 is formed on gate insulating film 8 to fill the inside of gate trench 6. Gate electrode 9 has an upper surface substantially as high as the upper surface of a portion of gate insulating film 8 on the upper surface of n type emitter contact layer 34.

Interlayer insulating film 10 is formed to cover gate electrode 9 as well as the portion of gate insulating film 8 extending onto the upper surface of n type emitter contact layer 34. By removing portions of interlayer insulating film 10 and gate insulating film 8, openings 11 are formed to expose portions of n type emitter contact layers 34 and p type contact regions 35. Emitter electrodes 42 are formed in contact with p type contact regions 35 and the portions of n type emitter contact layers 34 so as to fill the inside of openings 11. Emitter wire electrode 43 is formed in contact with the upper surface of each of emitter electrodes 42 so as to extend on the upper surface of interlayer insulating film 10.

Further, as with the semiconductor device shown in FIG. 1, collector electrode 44 and backside surface protecting electrode 15 are formed on the backside surface of substrate 31 opposite to its main surface on which n type epitaxial layer 32 is formed. As with the semiconductor device shown in FIG. 1, in the semiconductor device shown in FIG. 19, each of the side walls of gate trench 6 is inclined and substantially corresponds to one of the {0-33-8} plane and the {01-1-4} plane in a case where the silicon carbide layer constituting p type semiconductor layer 33 and the like is of hexagonal crystal type. Further, the inclined side wall of gate trench 6 substantially corresponds to the {100} plane in a case where the silicon carbide layer constituting p type semiconductor layer 33 and the like is of cubic crystal type. Also in this case, an effect similar to that of the semiconductor device shown in FIG. 1 can be obtained.

The following briefly describes operations of the semiconductor device shown in FIG. 19.

When a negative voltage is applied to gate electrode 9 and exceeds a threshold value, an inversion layer is formed at an end region (channel region) of p type semiconductor layer 33 that is in contact with gate insulating film 8 disposed lateral to gate electrode 9 and that faces gate trench 6. Accordingly, n type emitter contact layer 34 and n type epitaxial layer 32 serving as the breakdown voltage holding layer are electrically connected to each other. Thereby, electrons are injected from n type emitter contact layer 34 to n type epitaxial layer 32 serving as the breakdown voltage holding layer. Correspondingly, positive holes are supplied from substrate 31 to n type epitaxial layer 32 via p type epitaxial layer 36 serving as the buffer layer. As a result, conductivity modulation takes place in n type epitaxial layer 32 to significantly decrease a resistance between emitter electrode 42 and collector electrode 44. That is, the IGBT is brought into the ON state.

On the other hand, when the negative voltage applied to gate electrode 9 is equal to or smaller than the threshold value, the inversion layer is not formed in the channel region. Hence, the reverse-biased state is maintained between n type epitaxial layer 32 and p type semiconductor layer 33. As a result, the IGBT is brought into the OFF state, whereby no current flows therein.

Referring to FIG. 20 to FIG. 27, the following describes a method for manufacturing the semiconductor device of the second embodiment in accordance with the present invention.

First, referring to FIG. 20, on the main surface of substrate 31 made of silicon carbide, p type epitaxial layer 36 made of silicon carbide having p type conductivity is formed. Further, on p type epitaxial layer 36, n type epitaxial layer 32 of silicon carbide having n type conductivity is formed. N type epitaxial layer 32 serves as the breakdown voltage holding layer. P type epitaxial layer 36 and n type epitaxial layer 32 are formed by means of epitaxial growth employing the CVD method that utilizes a mixed gas of silane (SiH₄) and propane (C₃H₈) as a material gas, and utilizes hydrogen gas (H₂) as a carrier gas, for example. In doing so, it is preferable to introduce, for example, aluminum (Al) as an impurity of p type conductivity, and to introduce, for example, nitrogen (N) or phosphorus (P) as an impurity of n type conductivity.

Next, ions are implanted into the upper surface layer of n type epitaxial layer 32, thereby forming p type semiconductor layer 33 and n type emitter contact layer 34. In the ion implantation for forming p type semiconductor layer 33, ions of an impurity of p type conductivity such as aluminum (Al) are implanted. In doing so, by adjusting acceleration energy of the ions to be implanted, the depth of the region in which p type semiconductor layer 33 is to be formed can be adjusted.

Next, ions of an impurity of n type conductivity are implanted into n type epitaxial layer 32 thus having p type semiconductor layer 33 formed therein, thereby forming n type emitter contact layer 34. An exemplary, usable n type impurity is phosphorus or the like. In this way, a structure shown in FIG. 21 is obtained.

Next, as shown in FIG. 22, mask layer 17 is formed on the upper surface of n type emitter contact layer 34. As mask layer 17, an insulating film such as a silicon oxide film can be used. As a method for forming mask layer 17, the same method as the method for manufacturing mask layer 17 as illustrated in FIG. 6 can be used. As a result, mask layer 17 is formed which has an opening pattern in conformity with a region where vertical trench 16 shown in FIG. 22 is to be formed.

Then, using mask layer 17 as a mask, portions of n type emitter contact layer 34, p type semiconductor layer 33, and n type epitaxial layer 32 are removed by means of etching. As a method or the like for the etching, the same method can be used as that of the step illustrated in FIG. 6. In this way, a structure shown in FIG. 22 is obtained.

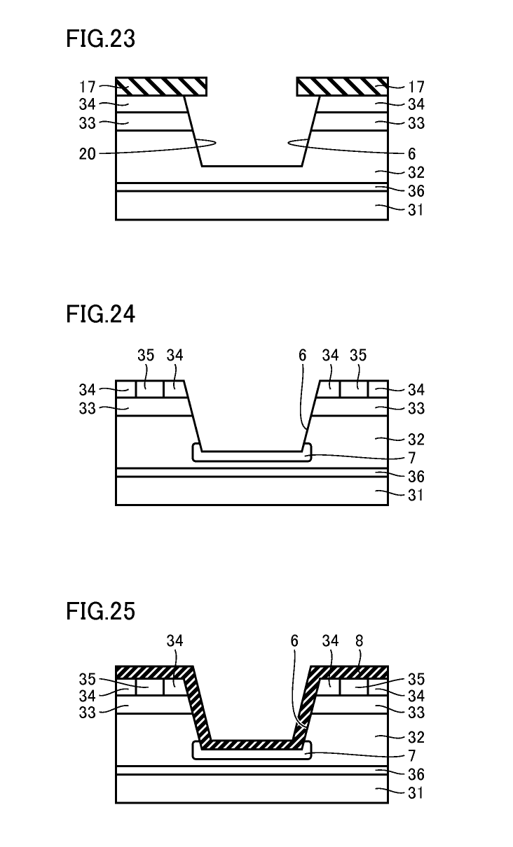

Next, a thermal etching step is performed to exhibit a predetermined crystal plane in each of n type epitaxial layer 32, p type semiconductor layer 33, and n type emitter contact layer 34. Conditions for this thermal etching step can be the same as the conditions for the thermal etching step described with reference to FIG. 7. As a result, gate trench 6 can be formed which has side walls 20 inclined relative to the main surface of substrate 31 as shown in FIG. 23. It should be noted that the plane orientation of the crystal plane exhibited at each of side walls 20 is, for example, {0-33-8}. In this way, a structure as shown in FIG. 23 is obtained.

Next, mask layer 17 is removed by means of any method such as etching. Thereafter, as with the step shown in FIG. 8, a resist film (not shown) having a predetermined pattern is formed using the photolithography method so as to extend from the inside of gate trench 6 onto the upper surface of n type emitter contact layer 34. As the resist film, there can be used a resist film having an opening pattern in conformity with the bottom portion of gate trench 6 and a portion of the upper surface of n type emitter contact layer 34. By implanting ions of an impurity of p type conductivity using this resist film as a mask, electric field relaxing region 7 is formed at the bottom portion of gate trench 6, and contact region 35 of p type conductivity is formed at the region of the portion of n type emitter contact layer 34. Thereafter, the resist film is removed. In this way, a structure as shown in FIG. 24 is obtained.

Then, an activation annealing step is performed to activate the impurity implanted by means of the above-described ion implantation. In this activation annealing step, as with the case of the above-described first embodiment in the present invention, annealing treatment is performed without forming a particular cap layer on the surface of the epitaxial layer made of silicon carbide (specifically, on side wall 20 of gate trench 6). It should be noted that the above-described cap layer may be formed before performing the activation annealing step. Alternatively, for example, the cap layer may be provided only on the upper surfaces of n type emitter contact layer 34 and p type contact region 35 before performing the activation annealing treatment.

Next, as shown in FIG. 25, gate insulating film 8 is formed to extend from the inside of gate trench 6 onto the upper surfaces of n type emitter contact layer 34 and p type contact region 35. Gate insulating film 8 is made of the same material as that for gate insulating film 8 shown in FIG. 9, and is formed by means of the same method as the method for forming gate insulating film 8 shown in FIG. 9. In this way, a structure shown in FIG. 25 is obtained.

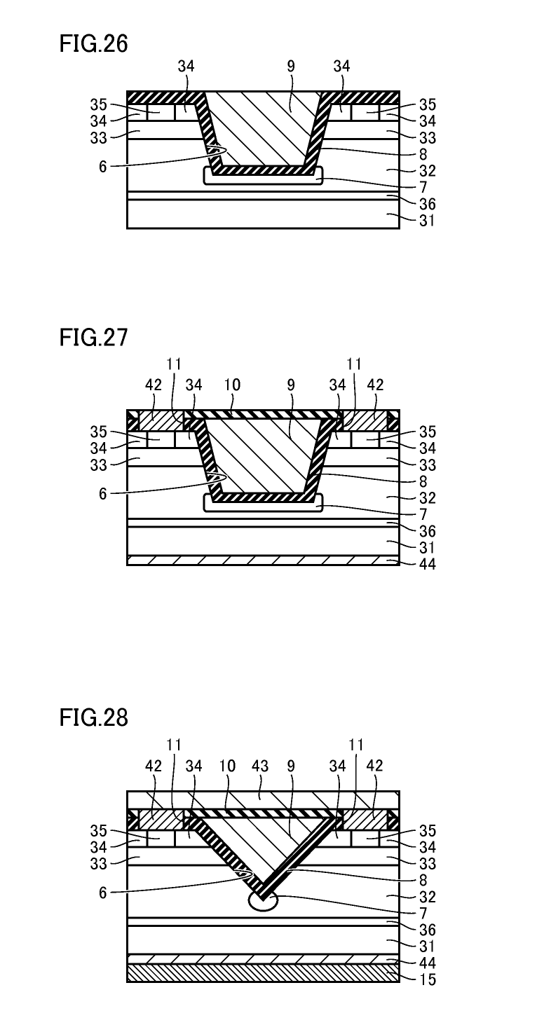

Next, as shown in FIG. 26, gate electrode 9 is formed on gate insulating film 8 to fill the inside of gate trench 6. Gate electrode 9 can be formed by means of the same method as the method for forming gate electrode 9 shown in FIG. 10. In this way, a structure shown in FIG. 26 is obtained.

Next, interlayer insulating film 10 (see FIG. 27) is formed to cover the upper surface of gate electrode 9 and the upper surface of gate insulating film 8 exposed on p type contact region 35. Interlayer insulating film 10 can be made of any material as long as the material is insulative. Further, as with the step shown in FIG. 11, openings 11 (see FIG. 27) are formed in interlayer insulating film 10 and gate insulating film 8.

Each of openings 11 is formed using the same method as the method for forming the openings in FIG. 11. Opening 11 has a bottom portion at which p type contact region 35 and a portion of n type emitter contact layer 34 are exposed.

Thereafter, using the same method as the method illustrated in FIG. 11, emitter electrode 42 is formed of a conductor film filling the inside of opening 11. This emitter electrode 42 is an ohmic electrode making ohmic contact with p type contact region 35 and n type emitter contact layer 34.

Further, collector electrode 44 (see FIG. 27) is formed on the backside surface of substrate 31 (the surface thereof opposite to the main surface thereof on which n type epitaxial layer 32 is formed). Collector electrode 44 can be made of any material as long as the material allows for ohmic contact with substrate 31. In this way, a structure shown in FIG. 27 is obtained.

Thereafter, an appropriate method such as the sputtering method is employed to form emitter wire electrode 43 (see FIG. 19) and backside surface protecting electrode 15 (see FIG. 19). Emitter wire electrode 43 makes contact with the upper surface of emitter electrode 42, and extends on the upper surface of interlayer insulating film 10. Backside surface protecting electrode 15 is formed on the surface of collector electrode 44. As a result, the semiconductor device shown in FIG. 19 can be obtained.

Next, referring to FIG. 28, a variation of the semiconductor device shown in FIG. 19 is described. A semiconductor device shown in FIG. 28 basically has the same configuration as that of the semiconductor device shown in FIG. 19, but is different therefrom in terms of the shape of gate trench 6. Specifically, in the semiconductor device shown in FIG. 28, gate trench 6 has a V-shaped cross sectional shape as with that of the semiconductor device shown in FIG. 18. At the bottom portion of gate trench 6 (the portion at which the lower portions of the opposite side walls are connected to each other), electric field relaxing region 7 is formed. With the semiconductor device thus configured, there can be provided the same effect as that of the semiconductor device shown in FIG. 19. Further, in the semiconductor device shown in FIG. 28, gate trench 6 does not have a flat bottom surface as shown in FIG. 19. Accordingly, gate trench 6 shown in FIG. 28 has a width narrower than that of gate trench 6 shown in FIG. 19. As a result, the semiconductor device shown in FIG. 28 can be reduced in size as compared with the semiconductor device shown in FIG. 19. This is advantageous in attaining finer design and higher integration in the semiconductor device.

It should be noted that, in the first or second embodiment described above, the opening pattern in the mask layer can have any shape, such as the shape of a line (for example, a stripe) or a curve. For example, as a shape of the mask layer, a plurality of island-like patterns each having a regular hexagonal planar shape may be aligned and arranged (for example, arranged to form a triangular lattice) with the opening pattern interposed therebetween. Further, the planar shape of the island-like pattern may be any shape other than a regular hexagon (for example, a polygon, a circle, an ellipse, or the like).

Further, the thermal etching may be performed with mask layer 17 remaining on the main surface of the silicon carbide layer. In this case, when the thermal etching is performed, mask layer 17 covers a region which is the main surface of the silicon carbide layer and is adjacent to vertical trench 16, and thus can prevent the main surface of the silicon carbide layer from being damaged by the thermal etching.

In the present specification, the case where side wall 20 of gate trench 6 corresponds to any one of the {0-33-8} plane, the {01-1-4} plane, and the {100} plane encompasses a case where there are a plurality of crystal planes constituting the side wall of gate trench 6, and the plurality of crystal planes include any one of the {0-33-8} plane, the {01-1-4} plane, and the {100} plane. The following specifically describes an exemplary case where the side wall of gate trench 6 corresponds to the {0-33-8} plane.

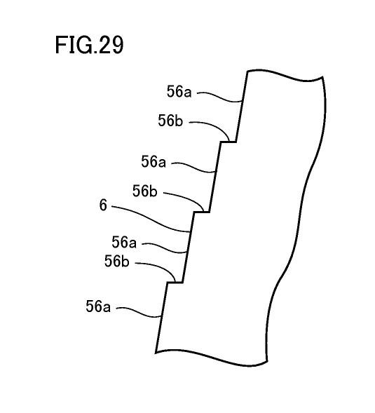

In the present invention, the {0-33-8} plane also includes a chemically stable plane constituted by, for example, alternately providing a plane 56a (first plane) and a plane 56b (second plane) in the side wall of gate trench 6 as shown in FIG. 29, microscopically. Plane 56a has a plane orientation of {0-33-8} whereas plane 56b, which is connected to plane 56a, has a plane orientation different from that of plane 56a. Here, the term “microscopically” refers to “minutely to such an extent that at least the size about twice as large as an interatomic spacing is considered”. Preferably, plane 56b has a plane orientation of {0-11-1}. Further, plane 56b in FIG. 29 may have a length (width) twice as large as the interatomic spacing of Si atoms (or C atoms), for example.

Further, the following describes an exemplary case where the side wall of the gate trench corresponds to the {01-1-4} plane. In the present invention, the {01-1-4} plane also includes a chemically stable plane constituted by alternately providing plane 56a (first plane) and plane 56b (second plane) as shown in FIG. 29, microscopically. Plane 56a has a plane orientation of {01-1-4} whereas plane 56b, which is connected to plane 56a, has a plane orientation different from that of plane 56a. Furthermore, the following describes an exemplary case where the side wall of the gate trench corresponds to the {100} plane. In the present invention, the {100} plane also includes a chemically stable plane constituted by alternately providing plane 56a (first plane) and plane 56b (second plane) as shown in FIG. 29, microscopically. Plane 56a has a plane orientation of {100} whereas plane 56b, which is connected to plane 56a, has a plane orientation different from that of plane 56a.

Further, the side wall of gate trench 6 may include at least two planes of equivalent plane orientations having six-fold symmetry in silicon carbide of hexagonal crystal type.

### Example

Experiments as described below were conducted to confirm the effect of the present invention.

(Samples)

Three substrates made of silicon carbide were prepared to form samples 1 to 3. Each substrate had a main surface having an off angle of 8° relative to the (0001) plane. Then, on the main surface of each substrate, an epitaxial layer of silicon carbide was formed. The epitaxial layer had a thickness of 10 μm.

Subsequently, on a surface of the epitaxial layer, a mask layer made of a silicon oxide film was formed using the CVD method. The mask layer had a thickness of 0.05 μm. Then, on the mask layer, a resist film having a pattern was formed using the photolithography method. The pattern of the resist film was configured such that island-like patterns each having a regular hexagonal planar shape were aligned with an opening interposed therebetween. A regular hexagon had a side length of 4.0 μm. The width of the opening (i.e., a distance between adjacent island-like patterns) was set to 4 ρm in sample 1, and 2 μm in samples 2 and 3.

(Description of Experiments)

Experiment 1:

Thermal etching was performed on samples 1 and 2 to remove the silicon carbide layer exposed between the island-like patterns, using the mask layer as a mask. Specifically, a mixed gas of oxygen gas and chlorine gas was used as a reactive gas, and the heat treatment temperature was set to 900° C. Further, the flow rate of the oxygen gas was set to 1.5 slm (Standard Liter per minute), and the flow rate of the chlorine gas was set to 1.5 slm. Furthermore, the treatment time was set to 15 minutes.

Experiment 2:

Reactive ion etching (RIE) was performed on sample 3 to remove silicon carbide exposed between the island-like patterns, using the mask layer as a mask, and form a trench. As process conditions for the RIE, the power was set to 800 W, the bias was set to 10 W, and the flow rate of SF₆ was set to 20 sccm (Standard Cubic Centimeter per minute).

In addition, thermal etching was performed after the RIE. Conditions for the thermal etching were basically the same as those in Experiment 1 described above, except for the treatment time. Specifically, the thermal etching was performed on sample 3 for 10 minutes.

(Results)

Result of Experiment 1:

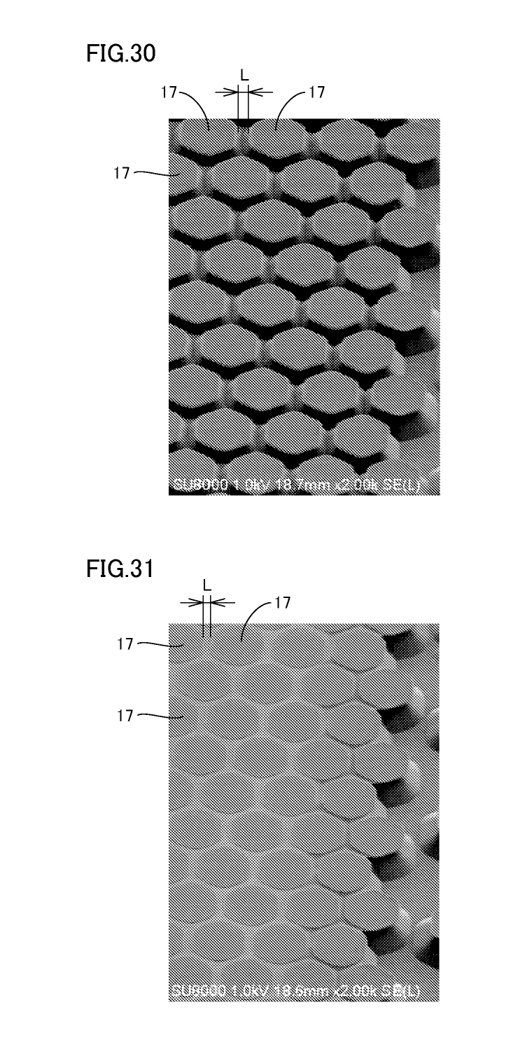

The result of experiment 1 is described with reference to FIG. 30 and FIG. 31. As can be seen in FIG. 30, in sample 1, the silicon carbide layer between mask layers 17 was removed by etching, and a gate trench was neatly formed. In sample 1 in which a width L of the opening as the distance between mask layers 17 was set to 4 μm, the silicon carbide layer exposed between mask layers 17 was removed by thermal etching, and the gate trench having inclined side walls was formed.

On the other hand, as shown in FIG. 31, in sample 2 in which width L of the opening between mask layers 17 was set to 2 μm, the silicon carbide layer exposed from the opening was not able to be sufficiently removed by thermal etching alone, and there remained a portion in which a gate trench was not fowled.

Result of Experiment 2:

In sample 3 processed in experiment 2, the silicon carbide layer exposed between mask layers 17 was almost removed, and a gate trench was thoroughly formed between mask layers 17, as with sample 1 shown in FIG. 30. Thus, even under the condition that the opening between mask layers 17 has a relatively narrow width of 2 μm, it was possible to form a gate trench in a reliable manner.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide semiconductor device, comprising the steps of:
preparing a silicon carbide layer having a main surface;
forming a mask layer on said main surface by a deposition method;
patterning said mask layer;
forming a gate trench having a side wall by removing a portion of said silicon carbide layer by etching using said patterned mask layer as a mask;
forming a gate insulating film on said side wall of said gate trench; and
forming a gate electrode on said gate insulating film,
wherein said silicon carbide layer has one of hexagonal and cubic crystal types, and said side wall of said gate trench substantially includes one of a {0-33-8} plane and a {01-1-4} plane in a case where said silicon carbide layer is of hexagonal crystal type, and substantially includes a {100} plane in a case where said silicon carbide layer is of cubic crystal type.

2. The method for manufacturing a silicon carbide semiconductor device according to claim 1, wherein said step of forming said mask layer is performed by depositing one or more materials selected from silicon oxide, silicon nitride, aluminum oxide, aluminum nitride, and gallium nitride.

3. The method for manufacturing a silicon carbide semiconductor device according to claim 1, wherein said step of forming said gate trench includes the step of performing thermal etching.

4. The method for manufacturing a silicon carbide semiconductor device according to claim 3, wherein said step of performing said thermal etching is performed by heating said silicon carbide layer while exposing said silicon carbide layer to a reactive gas containing oxygen and chlorine.

5. The method for manufacturing a silicon carbide semiconductor device according to claim 3, wherein said step of forming said gate trench includes the step of performing etching having a sputtering effect before performing said thermal etching.

6. The method for manufacturing a silicon carbide semiconductor device according to claim 5, wherein said etching having the sputtering effect is reactive ion etching.
